(19) United States
(12) Patent Application Publication
(10) Pub. No.: US 2012/0176256 A1
(43) Pub. Date: Jul. 12, 2012

(54) Primary base exponential line coding

(76) Inventor: Daniel E. South, Palmer, AK (US)

(21) Appl. No.: 12/930,625

(22) Filed: Jan. 12, 2011

(51) Int. Cl. H03M 7/00

(52) U.S. Cl. 341/51

(57) ABSTRACT

Line coding, or data coding at the physical layer of transmission, storage and retrieval has typically been previously by a digital representation of the actual binary coded value of a positional data bit in a byte. Bits are constructed into bytes of eight bits, words are constructed of two bytes, and so forth. Each more significant bit positional location in a typical eight bit byte is of greater value by a factor of two. This method of data coding is pervasive throughout modern information technology related devices, equipment and processing systems. In one embodiment of the invention—at bit location following that of 2⁴—the bit value of the bits in a byte or larger data word structure increase by double the exponent of the previous binary digit value. In another embodiment of the invention—at bit location following that of 2⁴—the bit value of the bits in a byte or larger data word structure increase to the square of the exponent of the previous binary digit value. Invented format enables massively more digital data easily be represented, stored, retrieved or transmitted by just one byte, word or larger data structure.

### CROSS REFERENCE TO OTHER APPLICATIONS

This utility patent application is a divisional application separating subject matter herein from “Exponential Line Coding” application originally filed Dec. 16, 2010 with USPO Express Mail Label # EG266365276US.

### FIELD OF THE INVENTION

The invention pertains to the field of data coding, especially in comparison and contrast to existing methods of base band data coding, or line coding, and related computer, networking, data storage and transmission and broadcast technology systems, methods and processes, and generally and pervasively relates to other aspects of information and electronic technology systems, methods and processes as well.

### BACKGROUND OF THE INVENTION

Line coding at the physical layer of transmission, storage and retrieval has typically been previously by a digital representation of the actual binary value of a data bit positionally coded within a data byte. Most typically, bits are constructed into bytes of eight bits, words are constructed of two bytes, and so forth.

Digital values of 0 or 1 (also analogous to Boolean algebra True/False and On/Off logic values) are represented or conveyed by high versus low voltages, or positive versus negative voltages, on a pair of wires, cable, or wireless by radio signals, or otherwise digitally represented or conveyed on other storage, presentation, processing, networking or transmission media, medium or means. Each more significant bit positional location in a typical eight bit byte is of greater binary value by a factor of two. This method of data coding is pervasive throughout modern information technology related equipment, and transmission and processing systems.

The dichotomy of a byte of data coded by this ubiquitous method follows: LSB: 2¹; BIT 1: 2¹; BIT 2: 2²; BIT 3: 2³; BIT 4: 2⁴; BIT 5: 2⁵; BIT 6: 2⁶; MSB: 2⁷

The least order bit (2⁰) of a byte is the LSB. Its OFF state represents a value of positional zero whereas its ON state represents a value of one. The next larger order bit (2¹) of a byte represents two when ON, and positional zero when OFF.

Thus a total range of values represented by the entire byte is from zero to 255, or commonly referred to 2⁸=256 bits.

Higher level protocols sometimes implement various additional higher layer systems and techniques of additional data coding, data transmission, storage and retrieval. Additional methods and techniques of combining multiple coded signals for wire or wireless transmission are also implemented to accomplish various purposes but underlying all such higher order systems is the actual physical layer line coding of digital data.

### BRIEF SUMMARY OF THE INVENTION

The invention includes a dramatically improved coding method to format and represent data to accomplish a decrease of the bandwidth required to transmit data at a certain rate, or to inversely raise the speed of transmission of a certain quantity of data. Physical media bulk data storage quantity requirements are also decreased greatly by the invention.

With the invention of Primary Base Exponential Line Coding a massive increase of the quantity of data represented, stored, retrieved or transmitted per byte, word or larger data structure is achieved at the lowest level of physical layer of data coding, also known as line coding. Primary Bases Exponential Line Coding conversion of data to more compact format may also be applied at higher level systems of data storage, processing, and transmission systems.

This is achieved by modifying existing positional binary linear step exponent line coding method to a system of wherein the higher order bit place code values are raised exponentially higher than each previous bit position value by its previous exponent squared. The lower bits code values remain the same.

The much larger code values can now be utilized to code massively higher values, yet the number of binary bit positions applied to physical media is eight bits a byte, and the lower significant bit positions required for precision of the first few least order bits of the byte of numerical code are retained.

The dichotomy of a data byte follows with exponents for invented format:

### METHOD “A”—Exponent Doubles After BIT 4 @ BIT LOCATION #5

### LSB: 2⁰; BIT 1: 2¹; BIT 2: 2²; BIT 3: 2³; BIT 4: 2 ⁴; BIT 5: 2⁸; BIT 6: 2¹⁶; MSB: 2³²

### METHOD “B”—Exponent Squares After BIT 4 @ BIT LOCATION #5

### LSB: 2⁰; BIT 1: 2¹; BIT 2: 2²; BIT 3: 2³; BIT 4: 2⁴; BIT 5: 2¹⁶; BIT 6: 2²⁵⁶; MSB: 2^{64K}

Invention requires and includes specialized yet similar conversion techniques for other number base formatted data such as decimal, hexadecimal, binary and the existing binary data coding formats predating conversion into the invented formats.

### BRIEF DESCRIPTION OF THE SEVERAL VIEWS OF THE DRAWING

The single drawing sheet details existing and invented coding systems:

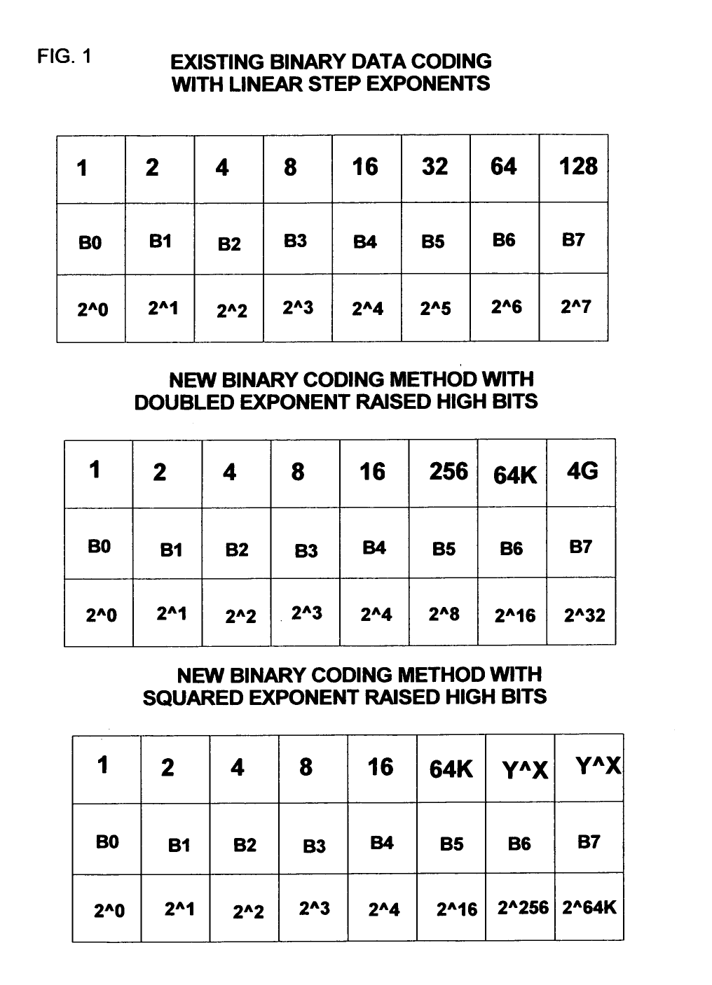

Sheet 1—FIG. 1
Set of three tables listing position values in systems of line coding:
Note the much greater size of data values shown that can be represented by higher order bits of a byte in the invented system.

### DETAILED DESCRIPTION OF THE INVENTION

Method “A” shown above is the preferred embodiment of invention.

Inventive step of Exponential Line Coding method permits a dramatically increasing quantity of data to be represented, stored, retrieved, processed or transmitted per code byte, word or larger data structure. Bigger digit positional code values means smaller physical data for digital bit storage and transmission and therefor consumes less resources to support the requested data operation.

Three level (or other prime numbers and fractions) numerical coding to physical media systems are sometimes used, but physical implementations of purely binary values have proven historically to most practicably reliable due to numerous physical phenomena such as characteristics of many data storage and transmission media, medium, means, systems, processes and methods.

Additional embodiments of the invention method and conversion process example are possible with other bases and exponent schemes and shorter or longer data words.

The invention may be constructed and implemented by persons or firms experienced in implementing previously existing types of digital data storage, processing, presentation and transmission systems, equipment, devices, components and related means.

1. is for Primary Base Exponential Line Coding methods of data coding, or line coding as specified herein.

2. is for the implementations of the methods of Primary Base Exponential Line Coding.

3. is for the processes of the various implementations of the Primary Bases Exponential Line Coding methods.
